(19) United States
(12) Patent Application Publication
(10) Pub. No.: US 2024/0014077 A1
(43) Pub. Date: Jan. 11, 2024

(54) Gate Isolation Regions and Fin Isolation Regions and Method Forming the Same

(71) Applicant: Taiwan Semiconductor Manufacturing Co., Ltd., Hsinchu (TW)

(72) Inventors: Bo-Cyuan Lu, New Taipei City (TW); Hsin-Che Chiang, Taipei City (TW); Tai-Chun Huang, Hsinchu (TW); Chi On Chui, Hsinchu (TW)

(21) Appl. No.: 18/150,642

(22) Filed: Jan. 5, 2023

Related U.S. Application Data
(60) Provisional application No. 63/377,276, filed on Sep. 27, 2022.
(60) Provisional application No. 63/367,828, filed on Jul. 7, 2022.

(51) Int. Cl. H01L 21/8238; H01L 27/092

(52) U.S. Cl. CPC H01L 21/823878; H01L 27/0924; H01L 21/823821

(57) ABSTRACT

A method includes forming a gate stack on a semiconductor region, etching the gate stack to form a first trench separating the gate stack into a first gate stack portion and a second gate stack portion, and forming a gate isolation region filling the first trench. The gate isolation region includes a silicon nitride liner, and a silicon oxide filling-region overlapping a first bottom portion of the silicon nitride liner. The method further includes etching the gate stack to form a second trench and to reveal a protruding semiconductor fin, and etching the protruding semiconductor fin to extend the second trench into the bulk semiconductor substrate. A fin isolation region is formed to fill the second trench. The fin isolation region includes a silicon oxide liner, and a silicon nitride filling-region overlapping a second bottom portion of the silicon oxide liner.

### PRIORITY CLAIM AND CROSS-REFERENCE

This application claims the benefit of the U.S. Provisional Application No. 63/377,276, filed Sep. 27, 2022, and entitled “Gate Isolation Regions and Fin Isolation Regions and Method Forming the Same,” and U.S. Provisional Application No. 63/367,828, filed Jul. 7, 2022, and entitled “Cut Metal Gate (CMG) and Continuous Metal On-Diffusion Edge (CMODE),” which applications are hereby incorporated herein by reference.

### BACKGROUND

Technological advances in Integrated Circuit (IC) materials and design have produced generations of ICs where each generation has smaller and more complex circuits than the previous generations. In the course of IC evolution, functional density (for example, the number of interconnected devices per chip area) has generally increased while geometry sizes have decreased. This scaling down process generally provides benefits by increasing production efficiency and lowering associated costs.

Such scaling down has also increased the complexity of processing and manufacturing ICs, and for these advances to be realized, similar developments in IC processing and manufacturing are needed. For example, Fin Field-Effect Transistors (FinFETs) have been introduced to replace planar transistors. The structures of FinFETs and methods of fabricating FinFETs are being developed.

The formation of FinFETs typically includes forming long semiconductor fins and long gate stacks, and then forming isolation regions to cut the long semiconductor fins and long gate stacks into shorter portions, so that the shorter portions may act as the fins and the gate stacks of FinFETs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-4, 5A, 5B, 6-7, 8A, 8B, 8C, 8D, 9A, 9B, 9C, 10A, 10B, 11, 12A, 12B, 13A-1, 13A-2, 13B, 14A, 14B, 15A, 15B, 15C, 15D, 16A, and 16B illustrate the cross-sectional views, perspective views, and top views of intermediate stages in the formation of Fin Field-Effect Transistors (FinFETs) and isolation regions in accordance with some embodiments.

FIG. 17 illustrates a process flow for forming FinFETs and isolation regions in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A method of forming isolation regions for isolating transistors are provided. In accordance with some embodiments, the isolation regions include gate isolation regions and fin isolation regions. The gate isolation regions are formed by cutting gate stacks and filling the corresponding trenches with a nitride liner and an oxide filling-region. Since the majority of materials in the gate isolation regions are oxide rather than nitride, the dielectric constant (k value) of the gate isolation regions is reduced, which may lead to reduced capacitance variation and improved ring oscillator performance. The fin isolation regions are formed by cutting protruding semiconductor fins (and the overlying gate stacks), and filling the corresponding trenches with an oxide liner and a nitride filling-region. By forming the oxide liner in addition to the nitride filling-region, the fin isolation regions have better leakage-prevention ability, and the breakdown voltage of the fin isolation regions is increased.

In the illustrated embodiments, the formation of Fin Field-Effect Transistors (FinFETs) is used as an example to explain the concept of the present disclosure. Other types of transistors such as planar transistors, Gate-All-Around (GAA) transistors, or the like may also adopt the concept of the present disclosure. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

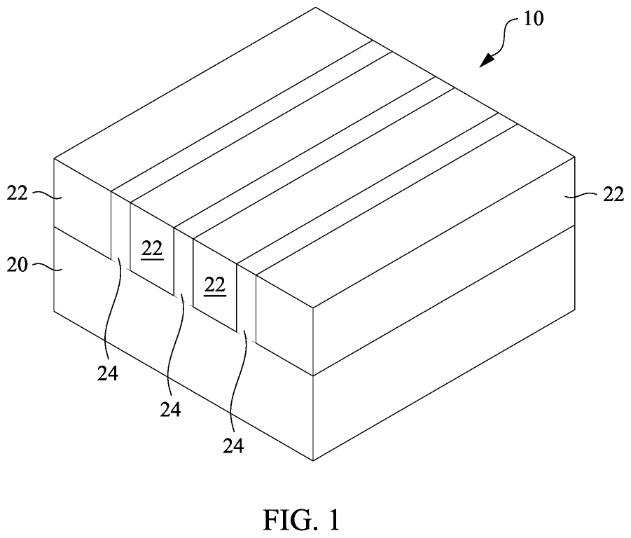

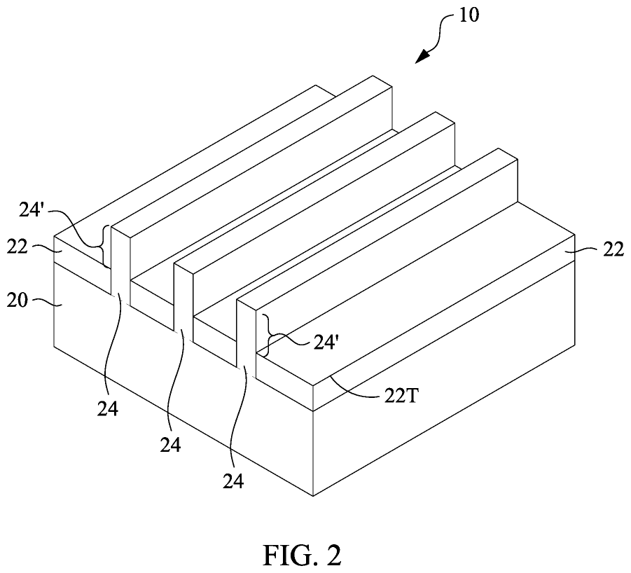

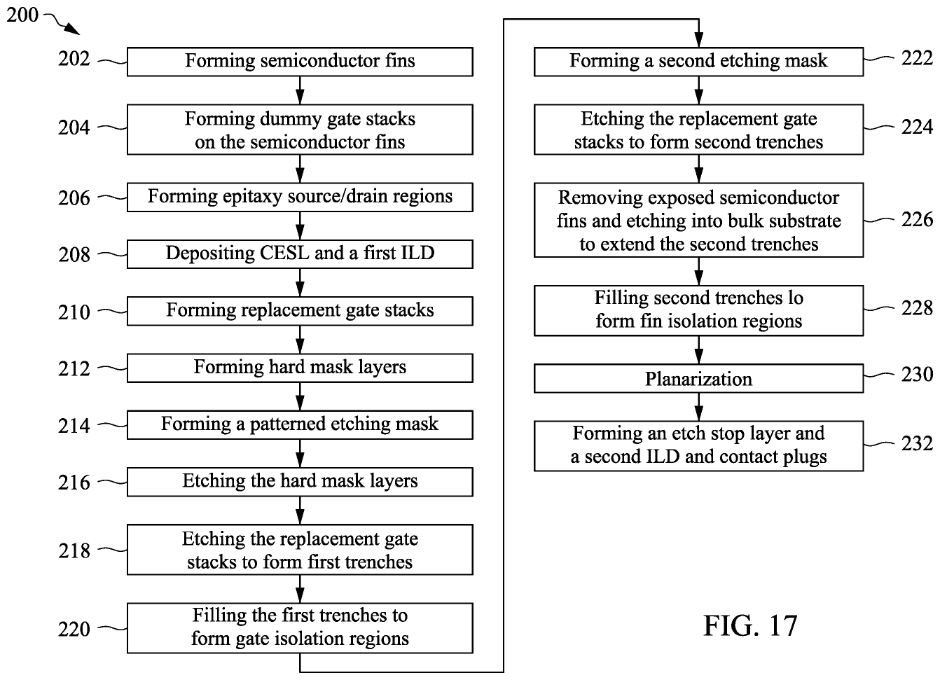

FIGS. 1-4, 5A, 5B, 6-7, 8A, 8B, 8C, 8D, 9A, 9B, 9C, 10A, 10B, 11, 12A, 12B, 13A-1, 13A-2, 13B, 14A, 14B, 15A, 15B, 15C, 15D, 16A, and 16B illustrate the perspective views, top views, and cross-sectional views of intermediate stages in the formation of FinFETs in accordance with some embodiments of the present disclosure. The corresponding processes are also reflected schematically in the process flow 200 as shown in FIG. 17.

FIG. 1 illustrates a perspective view of an initial structure. The initial structure includes wafer 10, which further includes substrate 20. Substrate 20 may be a semiconductor substrate, which may be a silicon substrate, a silicon germanium substrate, or a substrate formed of other semiconductor materials. Substrate 20 may be doped with a p-type or an n-type impurity. Isolation regions 22 such as Shallow Trench Isolation (STI) regions may be formed to extend from a top surface of substrate 20 into substrate 20. The portions of substrate 20 between neighboring STI regions 22 are referred to as semiconductor strips 24. The top surfaces of semiconductor strips 24 and the top surfaces of STI regions 22 may be substantially level with each other in accordance with some embodiments.

In accordance with some embodiments of the present disclosure, semiconductor strips 24 are parts of the original substrate 20, and hence the material of semiconductor strips 24 is the same as that of substrate 20. In accordance with alternative embodiments of the present disclosure, semiconductor strips 24 are replacement strips formed by etching the portions of substrate 20 between STI regions 22 to form recesses, and performing an epitaxy to regrow another semiconductor material in the recesses. Accordingly, semiconductor strips 24 are formed of a semiconductor material different from that of substrate 20. In accordance with some embodiments, semiconductor strips 24 are formed of silicon germanium, carbon-doped silicon, or a III-V compound semiconductor material.

STI regions 22 may include a liner oxide (not shown), which may be a thermal oxide formed through a thermal oxidation of a surface layer of substrate 20. The liner oxide may also be a deposited silicon oxide layer formed using, for example, Atomic Layer Deposition (ALD), High-Density Plasma Chemical Vapor Deposition (HDPCVD), Chemical Vapor Deposition (CVD), or the like. STI regions 22 may also include a dielectric material over the liner oxide, wherein the dielectric material may be formed using Flowable Chemical Vapor Deposition (FCVD), spin-on, or the like.

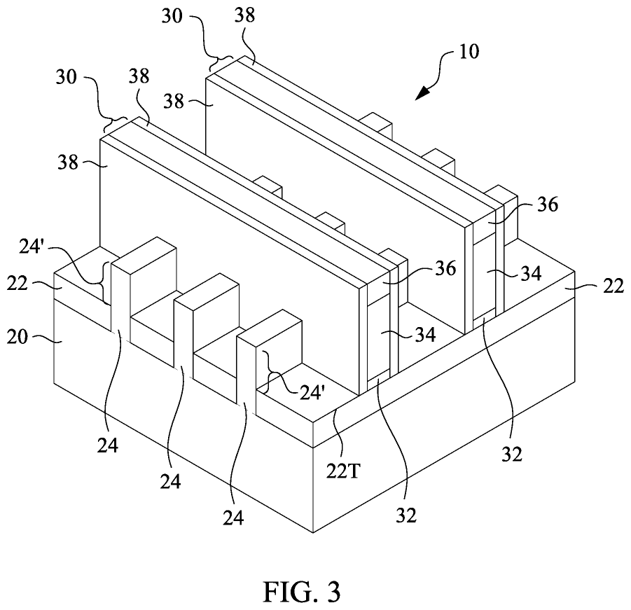

Referring to FIG. 2, STI regions 22 are recessed, so that the top portions of semiconductor strips 24 protrude higher than the top surfaces 22T of the remaining portions of STI regions 22 to form protruding fins 24′. The respective process is illustrated as process 202 in the process flow 200 as shown in FIG. 17. The etching may be performed using a dry etching process, wherein HF and NH₃, for example, may be used as the etching gases. During the etching process, plasma may be generated. Argon may also be included. In accordance with alternative embodiments of the present disclosure, the recessing of STI regions 22 is performed using a wet etch process. The etching chemical may include HF, for example.

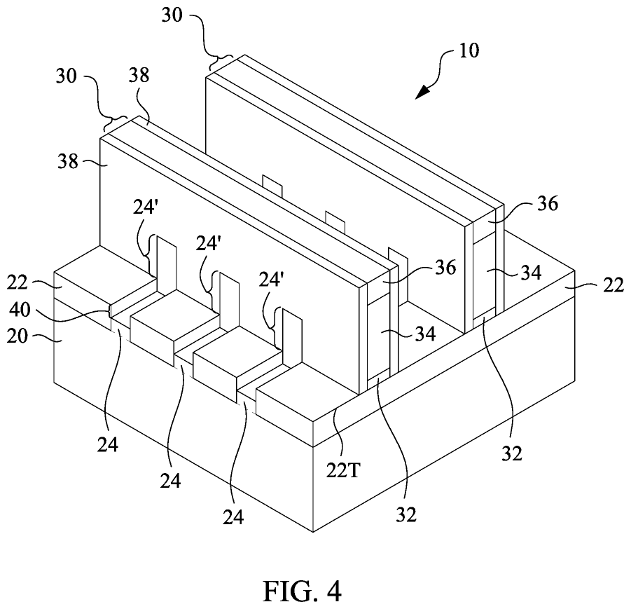

Referring to FIG. 3, dummy gate stacks 30 are formed on the top surfaces and the sidewalls of (protruding) fins 24′. The respective process is illustrated as process 204 in the process flow 200 as shown in FIG. 17. Dummy gate stacks 30 may include dummy gate dielectrics 32 and dummy gate electrodes 34 over dummy gate dielectrics 32. Dummy gate dielectrics 32 may be formed of or comprise silicon oxide. Dummy gate electrodes 34 may be formed, for example, using polysilicon or amorphous silicon, and other materials may also be used. Each of dummy gate stacks 30 may also include one (or a plurality of) hard mask layer 36 over dummy gate electrodes 34. Hard mask layers 36 may be formed of silicon nitride, silicon oxide, silicon carbo-nitride, or multi-layers thereof. Dummy gate stacks 30 may cross over a plurality of protruding fins 24′ and STI regions 22. Dummy gate stacks 30 also have lengthwise directions perpendicular to the lengthwise directions of protruding fins 24′.

Next, gate spacers 38 are formed on the sidewalls of dummy gate stacks 30. In accordance with some embodiments of the present disclosure, gate spacers 38 are formed of a dielectric material such as silicon nitride, silicon carbo-nitride, or the like, and may have a single-layer structure or a multi-layer structure including a plurality of dielectric layers.

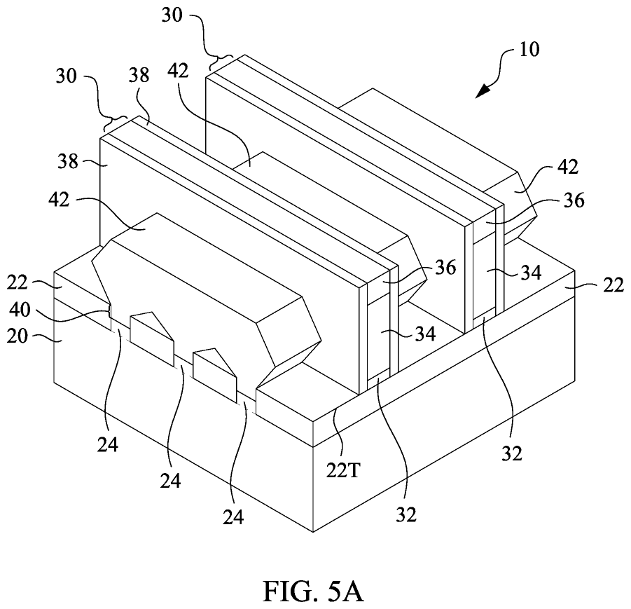

A recessing process is then performed to etch the portions of protruding fins 24′ that are not covered by dummy gate stacks 30 and gate spacers 38, resulting in the structure shown in FIG. 4. The recessing may be anisotropic, and hence the portions of fins 24′ directly underlying dummy gate stacks 30 and gate spacers 38 are protected, and are not etched. The top surfaces of the recessed semiconductor strips 24 may be lower than the top surfaces 22T of STI regions 22 in accordance with some embodiments. Recesses 40 are accordingly formed between STI regions 22. Recesses 40 are located on the opposite sides of dummy gate stacks 30.

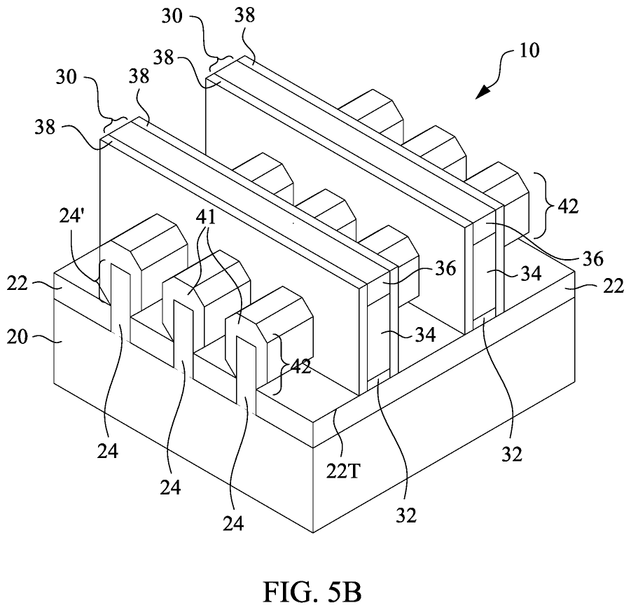

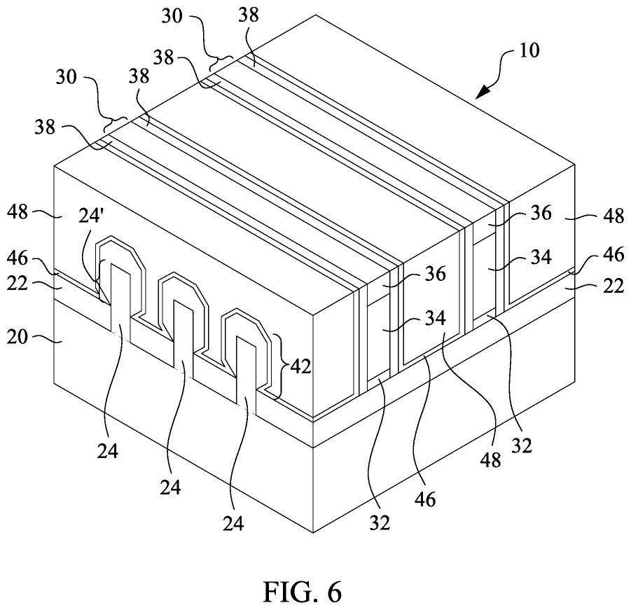

Next, epitaxy regions (source/drain regions) 42 are formed by selectively growing a semiconductor material from recesses 40, resulting in the structure in FIG. 5A. The respective process is illustrated as process 206 in the process flow 200 as shown in FIG. 17. Source/drain region(s) may refer to a source or a drain, individually or collectively dependent upon the context. In accordance with some embodiments, epitaxy regions 42 include silicon germanium, carbon-doped silicon, or silicon. Depending on whether the resulting FinFET is a p-type FinFET or an n-type FinFET, a p-type or an n-type impurity may be in-situ doped with the proceeding of the epitaxy process. For example, when the resulting FinFET is a p-type FinFET, silicon germanium boron (SiGeB) may be grown. Conversely, when the resulting FinFET is an n-type FinFET, silicon phosphorous (SiP) or silicon carbon phosphorous (SiCP) may be grown. After epitaxy regions 42 fully fill recesses 40, epitaxy regions 42 start expanding horizontally, and facets may be formed.

After the epitaxy process, epitaxy regions 42 may be further implanted with a p-type or an n-type impurity to form source and drain regions, which are also denoted using reference numeral 42. In accordance with alternative embodiments of the present disclosure, the implantation process is skipped when epitaxy regions 42 are in-situ doped with the p-type or n-type impurity during the epitaxy to form source/drain regions. Epitaxy source/drain regions 42 include lower portions that are formed in STI regions 22, and upper portions that are formed over the top surfaces of STI regions 22.

FIG. 5B illustrates the formation of source/drain regions 42 in accordance with alternative embodiments of the present disclosure. In accordance with these embodiments, the protruding fins 24′ as shown in FIG. 3 are not recessed, and epitaxy regions 41 are grown on protruding fins 24′. The material of epitaxy regions 41 may be similar to the material of the epitaxy semiconductor material 42 as shown in FIG. 5A, depending on whether the resulting FinFET is a p-type or an n-type FinFET. Accordingly, source/drain regions 42 include protruding fins 24′ and the epitaxy regions 41. An implantation process may be performed to implant an n-type impurity or a p-type impurity.

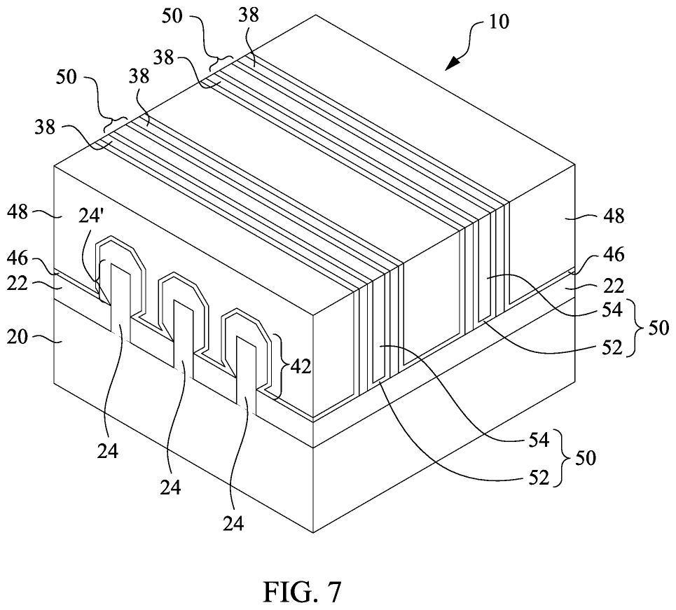

FIG. 6 illustrates a perspective view of the structure after the formation of Contact Etch Stop Layer (CESL) 46 and Inter-Layer Dielectric (ILD) 48. The respective process is illustrated as process 208 in the process flow 200 as shown in FIG. 17. In accordance with some embodiments of the present disclosure, CESL 46 may be formed of or comprise silicon oxide, silicon nitride, silicon carbide, silicon carbonitride, or the like, or combinations thereof. CESL 46 may be formed using a conformal deposition method such as ALD or CVD, for example. ILD 48 may include a dielectric material formed using, for example, FCVD, spin-on coating, CVD, or another deposition method. ILD 48 may also be formed of an oxygen-containing dielectric material, which may be a silicon-oxide based dielectric material such as silicon oxide, Phospho-Silicate Glass (PSG), Boro-Silicate Glass (BSG), Boron-Doped Phospho-Silicate Glass (BPSG), or the like. A planarization process such as a Chemical Mechanical Polish (CMP) process or a mechanical grinding process may be performed to level the top surfaces of ILD 48, dummy gate stacks 30, and gate spacers 38 with each other.

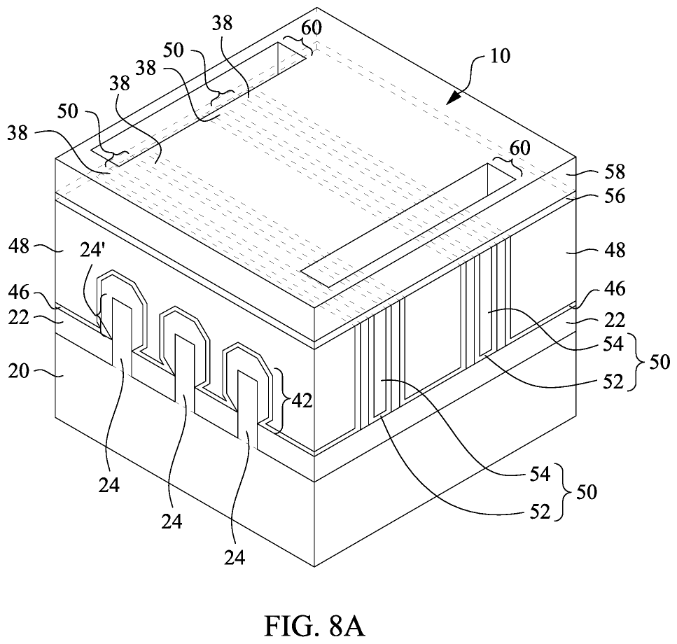

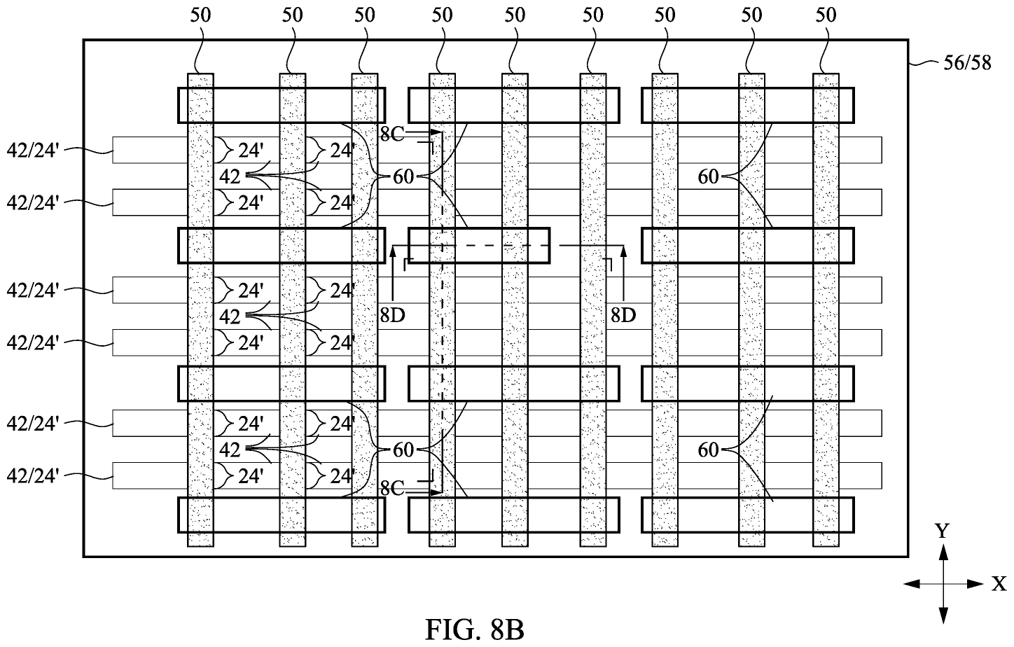

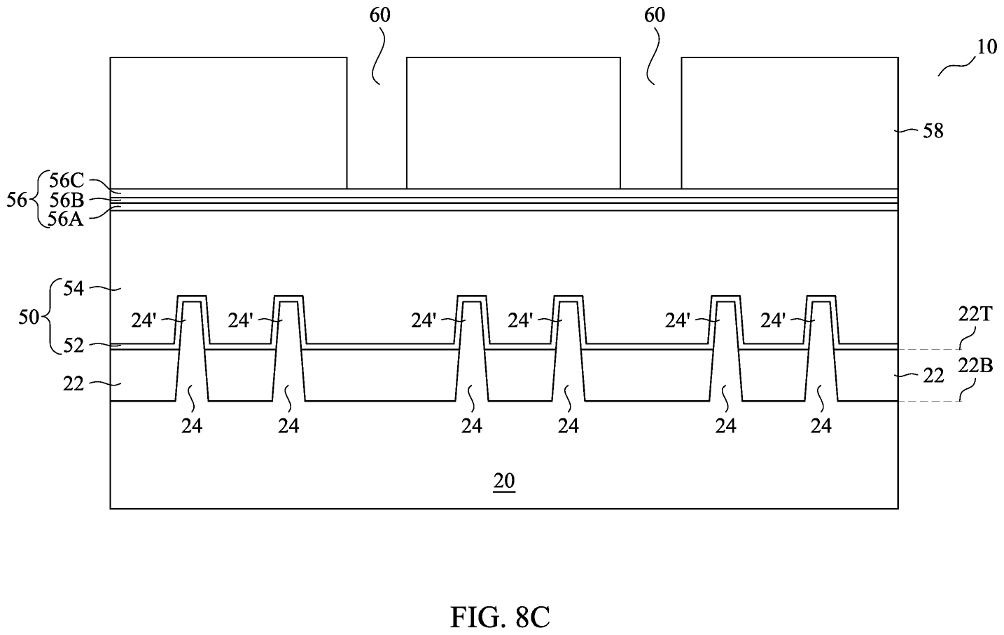

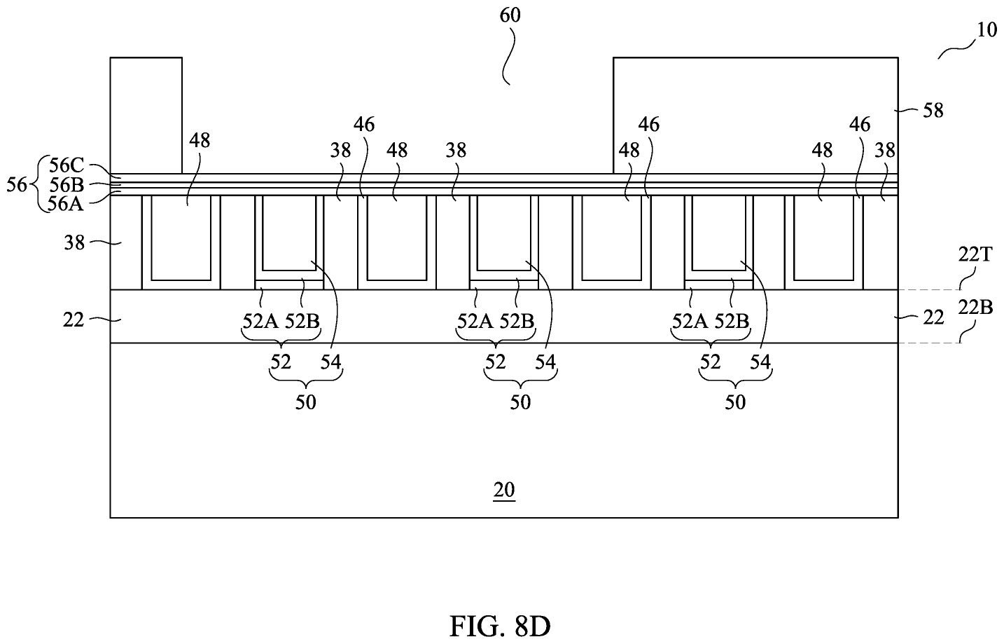

FIG. 7 illustrates the formation of replacement gate stacks 50. The respective process is illustrated as process 210 in the process flow 200 as shown in FIG. 17. The formation process includes removing the dummy gate stacks 30 to form trenches, and forming replacement gate stacks 50 in the resulting trenches. In accordance with some embodiments, gate stacks 50 include gate dielectrics 52 (including interfacial layers 52A and high-k dielectric layers 52B, FIG. 8D), and gate electrodes 54. Interfacial layers 52A may include silicon oxide. High-k dielectric layers 52B may include hafnium oxide, zirconium oxide, lanthanum oxide, and/or the like. Gate electrodes 54 may include TiN, TiSiN, TaN, TiAlN, TiAl, cobalt, tungsten, and/or the like. Accordingly, gate electrodes 54 are also referred to as metal gates 54.

Next, the formation process proceeds to the cutting of gate stacks 50 and the cutting of protruding fins 24′ in order to form isolated transistors. The cutting of gate stacks 50 is referred to as a Cut Metal Gate (CMG) process. The cutting of protruding semiconductor fins 24′ is referred to as a Continuous Metal On-Diffusion Edge (CMODE) process, or sometimes referred to as a Cut Metal on-Diffusion Edge (CMODE) process. It is appreciated that in the illustrated example embodiments, a CMODE process is performed, in which the cutting of protruding semiconductor fins 24′ is performed after the formation of replacement gate stacks 50. In accordance with alternative embodiments, the cutting of protruding semiconductor fins 24′ is performed before the formation of replacement gate stacks 50, and dummy gate stacks 30 (FIG. 6) are cut. The corresponding process are thus referred to as a Continuous Poly On Diffusion Edge (CPODE) process or a Cut Poly On Diffusion Edge (CPODE) process. In the illustrated CMG process and CMODE process, some examples of the cutting positions are illustrated, as shown in FIG. 8B. It is appreciated that the cutting processes may be performed at different positions and with different sizes, depending on the design of the transistors.

FIGS. 8A and 8B illustrate a perspective view and a top view, respectively, in the formation of hard mask layer 56, etching mask 58, and the corresponding openings in etching mask 58. FIG. 8C illustrates a cross-sectional view obtained from the cross-section 8C-8C in FIG. 8B. FIG. 8D illustrates a cross-sectional view obtained from the cross-section 8D-8D in FIG. 8B. As shown in FIG. 8B, a plurality of protruding fins 24′ and source/drain regions 42 have lengthwise directions extending parallel to the X-direction, and replacement gate stacks 50 having lengthwise directions parallel to the Y-direction. Protruding fins 24′ are directly under replacement gate stacks 50. Source/drain regions 42 are formed between replacement gate stacks 50. ILD 48 and CESL 46 and gate spacers 38 (FIG. 7) are not shown in FIG. 8A. In accordance with some embodiments, each of openings 60 extends to overlap a single one or a plurality of replacement gate stacks 50, depending on the circuit design.

In accordance with some embodiments, hard mask layers 56 are deposited, and includes a multi-layer structure. The respective process is illustrated as process 212 in the process flow 200 as shown in FIG. 17. For example, FIGS. 8C and 8D illustrate an example in which hard mask layers 56 include silicon nitride layer 56A, silicon layer 56B, and silicon nitride layer 56C. In accordance with alternative embodiments, a single-layer hard mask 56 is used, which may be formed of or comprise silicon nitride.

Etching mask 58 is then formed, as shown in FIGS. 8A, 8C, and 8D. The respective process is illustrated as process 214 in the process flow 200 as shown in FIG. 17. Etching mask 58 may also have a single-layer structure (which may include a photoresist) or a dual-layer structure including a Bottom Anti-reflective Coating (BARC) and a photoresist. Alternatively, etching mask 58 may have a tri-layer, which may include a bottom layer, a middle layer over the bottom layer, and a top layer, which may be a patterned photoresist. Openings 60 are formed in etching mask 58. In FIGS. 8C and 8D and some subsequent figures, line 22T represents the level of the top surfaces of STI regions 22, and line 22B represents the level of the bottom surfaces of STI regions 22. STI regions 22 are at the level between lines 22T and 22B, which represent the top surfaces and bottom surfaces, respectively, of STI regions 22.

Next, etching mask 58 is used to etch mask layers 56. The respective process is illustrated as process 216 in the process flow 200 as shown in FIG. 17. In accordance with some embodiments, the etching process includes a main etching process followed by an over-etching process. Depending on the materials of mask layers 56, the main etching process may be performed using process gases selected from CH₂F₂, CF₄, O₂, Ar, and combinations thereof. The over-etching process may be performed using process gases selected from CH₃F, O₂, Ar, and combinations thereof. The etching may be anisotropic.

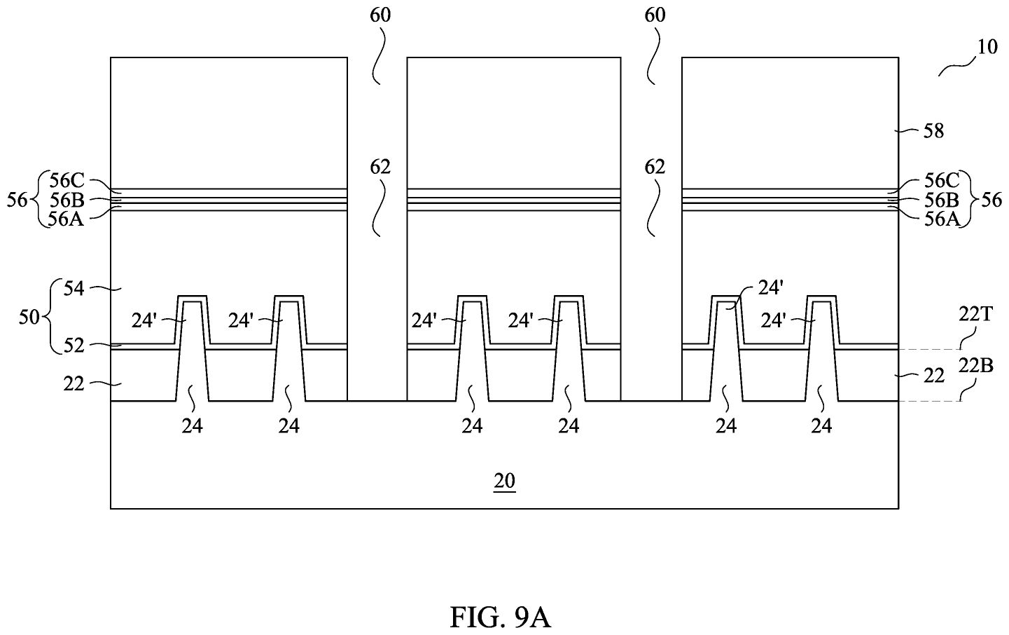

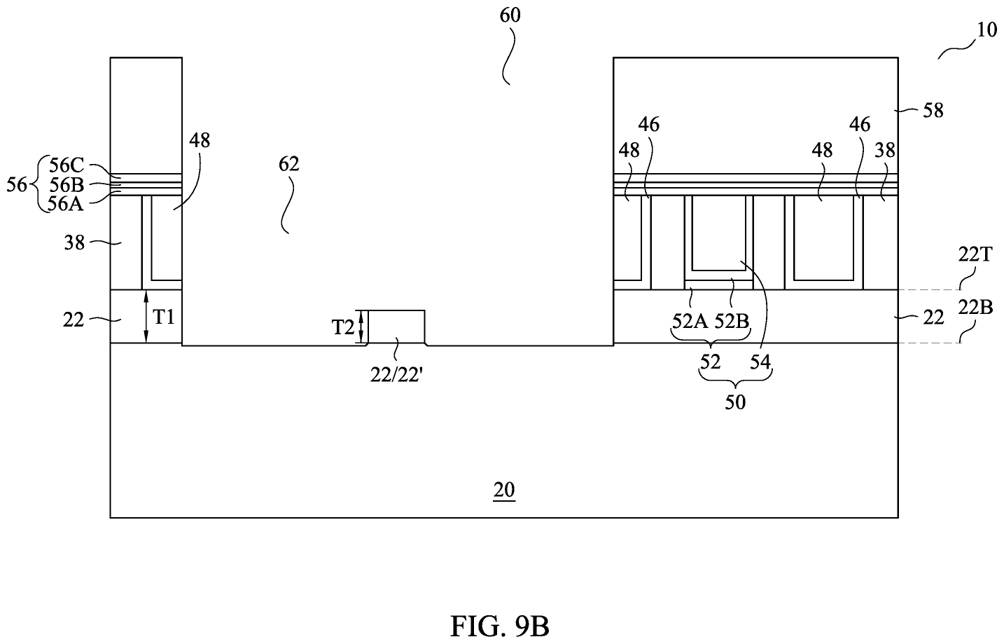

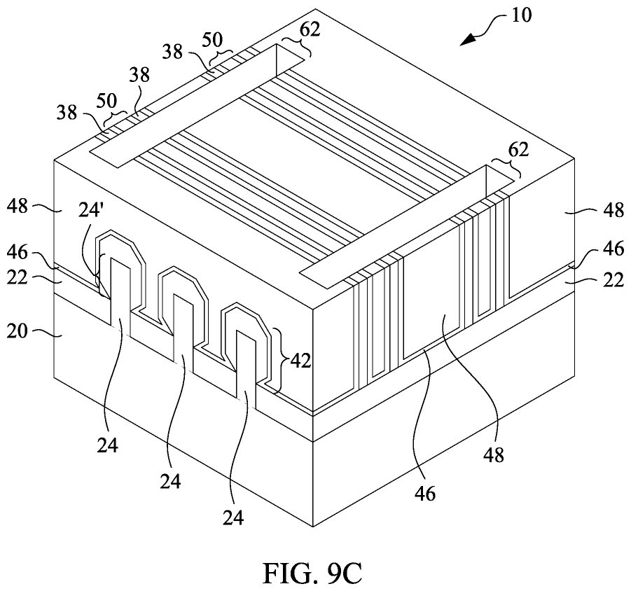

Next, the exposed portions of replacement gate stacks 50 are etched. The respective process is illustrated as process 218 in the process flow 200 as shown in FIG. 17. The resulting structures are shown in FIGS. 9A and 9B, which illustrate cross-sectional views. Trenches 62 are thus formed in replacement gate stacks 50, as shown in FIGS. 9A and 9B, which are obtained from the same planes as FIGS. 8C and 8D, respectively. Trenches 62 thus extend into replacement gate stacks 50. Before etching replacement gate stacks 50, etching mask 58 may be (or may not be) removed. The etching of replacement gate stacks 50 are anisotropic. In accordance with some embodiments, the etching is performed until STI regions 22 are etched-through, and the etching process stops on the top surface of the bulk portion of semiconductor substrate 20. In accordance with alternative embodiments, the etching stops on the top surfaces of STI regions 22. After the etching process, etching mask 58 is removed if it has not been removed in proceeding processes. FIG. 9C illustrates a perspective view of wafer 10, which shows the formation of trenches 62.

In the etching process, gate spacers 38 and ILD 48 may also be etched, as shown in FIGS. 9B and 9C. In accordance with some embodiments, as shown in FIG. 9B, there may be some residue portions of STI regions 22 (marked as 22′) left due to the topology. STI residue portions 22′ may have a reduced thickness T2 smaller than the thickness T1 of STI regions 22 that are not etched. For example, the ratio T2/T1 may be smaller than about 0.7 in accordance with some embodiments. In accordance with alternative embodiments, the portions of STI regions 22 directly underlying trench 62 are all removed, and the illustrated STI residue portions 22′ does not remain.

FIG. 9C illustrates a perspective view of trenches 62 in accordance with some embodiments. Hard mask layers 56 are not shown in FIG. 9C (although they exist at this time), so that the relationship of trenches 62 with other features such as replacement gate stacks 50, CESL 46, ILD 48, and gate spacers 38 may be viewed.

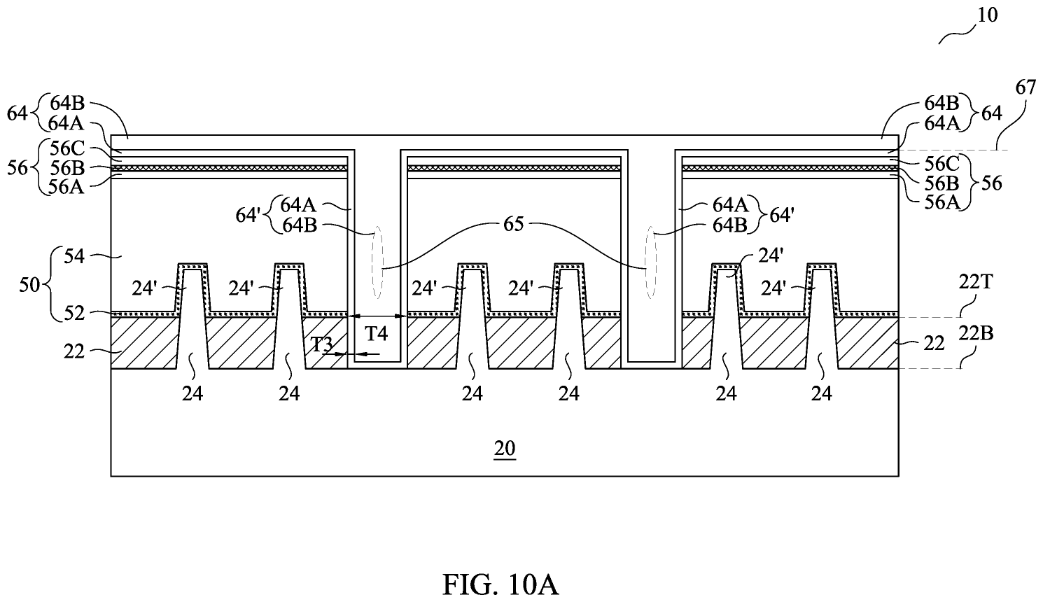

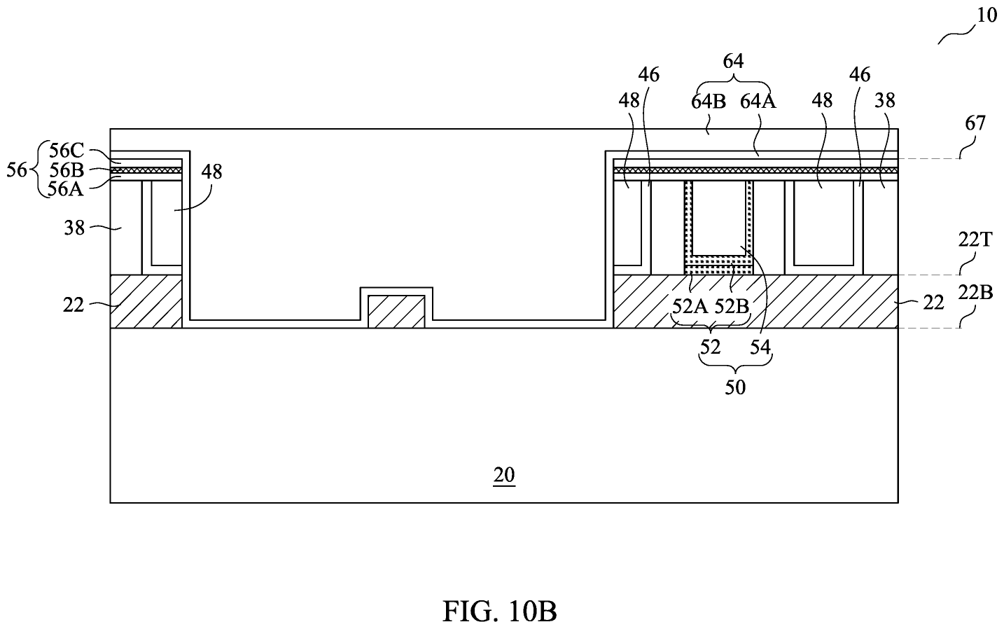

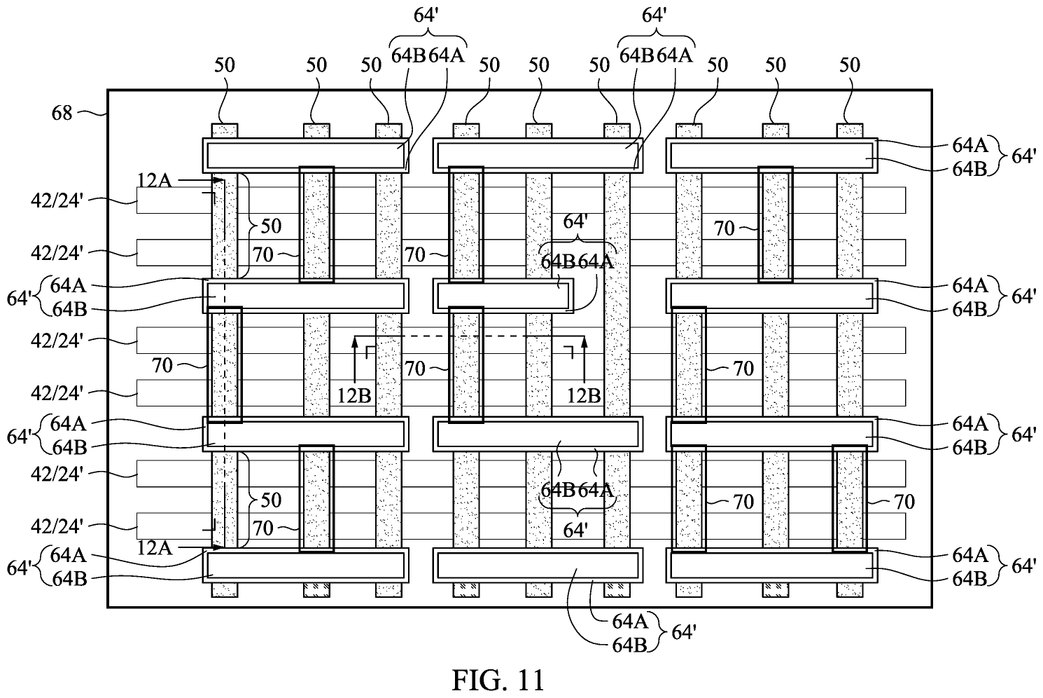

In a subsequent process, dielectric layers 64 (including dielectric liner 64A and dielectric filling-region 64B) are deposited, as shown in FIGS. 10A and 10B, which are also obtained from the same planes as FIGS. 9A and 9B, respectively. The respective process is illustrated as process 220 in the process flow 200 as shown in FIG. 17. Dielectric layers 64 include some portions extending into trenches 62 (FIGS. 9A and 9B) to form isolation regions, and some horizontal portions over the top surfaces of mask layers 56, ILD 48, and gate spacers 38 (shown in FIG. 9C).

In accordance with some embodiments, dielectric layers 64 include dielectric liner 64A, and dielectric filling-region 64B over dielectric liner 64A. The materials of dielectric liner 64A and dielectric filling-region 64B are different from each other. Dielectric liner 64A may have a higher nitrogen atomic percentage than dielectric filling-region 64B, and dielectric filling-region 64B may have a higher oxygen atomic percentage than dielectric liner 64A. In accordance with some embodiments, dielectric liner 64A is formed of silicon nitride, and is free from oxygen therein, and dielectric filling-region 64B is formed of silicon oxide, and is free from nitrogen therein. There may be, or may not be, seams 65 formed in dielectric filling-region 64B.

In accordance with alternative embodiments, both of dielectric liner 64A and dielectric filling-region 64B comprise silicon oxynitride, and the nitrogen atomic percentage in dielectric liner 64A is higher than the nitrogen atomic percentage in dielectric filling-region 64B. For example, the oxygen atomic percentage in dielectric liner 64A may be in the range between about 5 percent and about 40 percent, and the oxygen atomic percentage in dielectric filling-region 64B may be in the range between about 40 percent and about 70 percent. On the other hand, the nitrogen atomic percentage in dielectric liner 64A may be in the range between about 40 percent and about 70 percent, and the oxygen atomic percentage in dielectric filling-region 64B may be in the range 5 percent and about 40 percent.

In accordance with some embodiment, either one or both of dielectric liner 64A and dielectric filling-region 64B are deposited as having a uniform composition with a uniform silicon atomic percentage, a uniform oxygen atomic percentage, and a uniform nitrogen atomic percentage. In accordance with alternative embodiments, either one or both of dielectric liner 64A and dielectric filling-region 64B includes a portion that has gradually changed atomic percentages of nitrogen and oxygen. For example, dielectric liner 64A may be formed of silicon nitride (or SiON), and the process gases are gradually changed to increase the flow of the precursor for adding oxygen, so that more oxygen may be added, and to reduce the flow of the precursor for adding nitrogen. There may be, or may not be, a bottom layer of silicon nitride or SiON (having a uniform composition) to be formed. The process condition may be changed until a top most layer is a silicon oxide layer or a SiON layer. In accordance with these embodiments, the gradually changed layer and the top silicon oxide layer or SiON layer may be collectively considered as parts of dielectric filling-region 64B, while the bottom silicon nitride layer or SiON layer may be considered as the dielectric liner 64A.

In accordance with some embodiments, each of dielectric liner 64A and dielectric filling-region 64B may be formed using ALD, CVD, or the like. The precursors for forming silicon nitride may include a nitrogen-containing gas such as NH₃, N₂, and/or the like, and a silicon-containing gas such as silane (SiH₄), disilane (Si₂H₄), DiChloroSilane (DCS, SiH₂Cl₂), and/or the like. The precursors for forming silicon oxide may include SiCl₄, H₂O, polysilazane, trisilylamine (TSA), an organoaminosilane, O₂, and/or the like. The precursors for forming SiON may include the above-mentioned precursors for forming silicon oxide and the precursors for forming silicon nitride.

The formation of silicon nitride may be performed adopting process conditions including a wafer temperature in the range between about 350° C. and about 450° C. The chamber pressure of the deposition chamber may be in the range between about 2 Torr and about 5 Torr. The RF power may be in the range between about 400 watts and about 500 watts. The formation of silicon oxide may be performed adopting process conditions including a wafer temperature in the range between about 200° C. and about 300° C. The chamber pressure of the deposition chamber may be in the range between about 2.5 Torr and about 5 Torr. The RF power may be in the range between about 150 watts and about 500 watts.

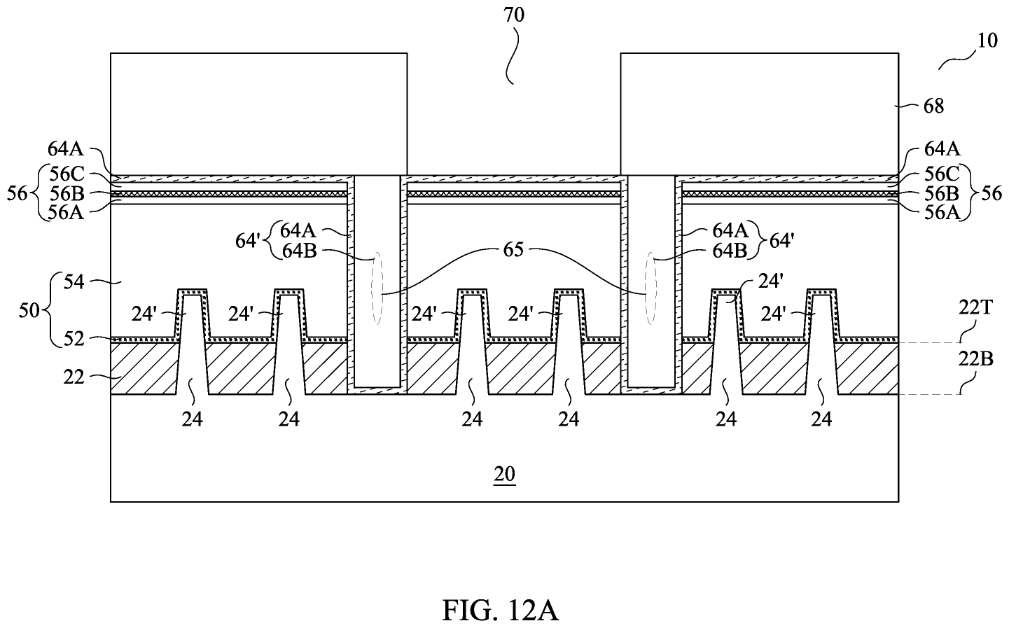

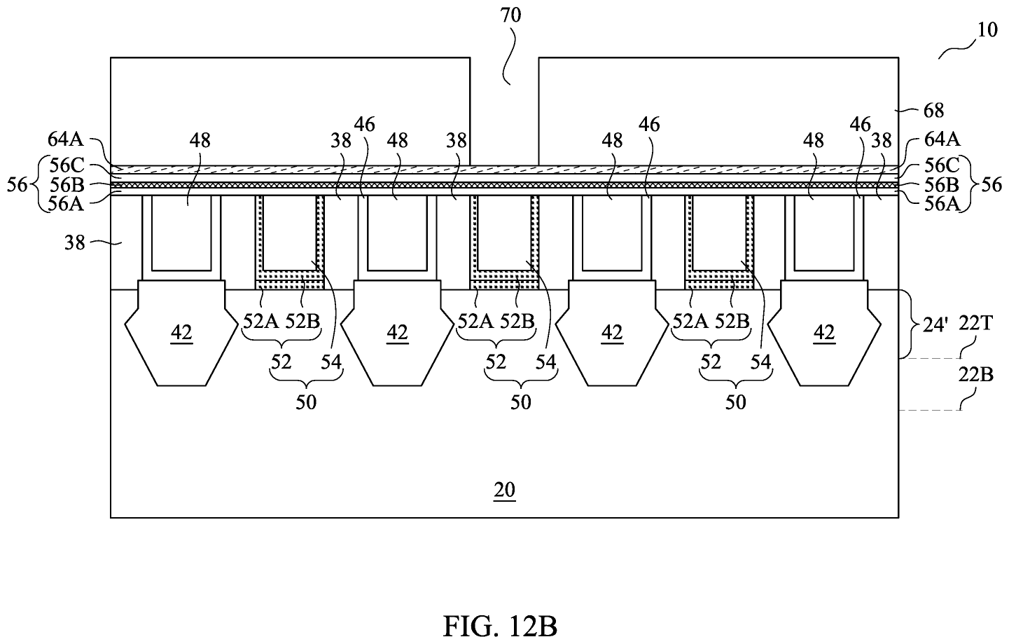

In accordance with some embodiment, the thickness of dielectric liner 64A is controlled to be not too thin and not too thick. If dielectric liner 64A (which may comprise SiN that has a higher k value than silicon oxide) is too thick, or the entire trenches 62 are filled with SiN, the k value of the resulting gate isolation region 64′ (FIG. 12A) will be too high. This causes the capacitance variation to be high, and ring oscillator performance to be degraded. If dielectric liner 64A is too thin (or there is no dielectric liner 64A, and silicon oxide occupies the entire trenches 62), the threshold voltage of the neighboring FinFET will be undesirably shifted. In accordance with some embodiment, the thickness ratio T3/T4 (FIG. 10A) may be smaller than about 0.1, or may be smaller than about 0.05, wherein thickness T3 is the thickness of dielectric liner 64A, and thickness T4 is the total thickness of dielectric liner 64A and dielectric filling-region 64B. Thicknesses T3 and T4 may be measured at the same level as the interface between replacement gate stack 50 and STI regions 22.

After the deposition of dielectric liner 64A and dielectric filling-region 64B, a planarization process such as a CMP process or a mechanical grinding process is performed. The planarization process may be stopped on the top horizontal portions of dielectric liner 64A, and FIGS. 10A and 10B illustrate levels 67, at which the planarization process is stopped. The remaining portions of dielectric liner 64A and dielectric filling-region 64B are collectively referred to as gate isolation regions 64′ hereinafter, and may be alternatively referred to as dielectric plugs 64′.

Next, as shown in FIGS. 11, 12A and 12B, which illustrate a top view and cross-sectional views, etching mask 68 is formed to cover wafer 10, followed by patterning etching mask 68 to form openings 70. The respective process is illustrated as process 222 in the process flow 200 as shown in FIG. 17. FIG. 12A illustrates the cross-sectional view of the structure shown in FIG. 11, wherein the cross-sectional view is obtained from the cross-section 12A-12A in FIG. 11. FIG. 12B illustrates the cross-section 12B-12B in FIG. 11. Similarly, etching mask 68 may be a single-layer etching mask including a photoresist, a dual-layer etching mask including a photoresist and a bottom anti-reflective coating, or a tri-layer etching mask. Each of openings 70 is formed overlapping a portion of replacement gate stack 50, which exposed portion may be between two neighboring gate isolation regions 64′. Referring to FIG. 12A, the edges of etching mask 68 may be vertically aligned to the edges of gate isolation regions 64′. The edge portions of gate isolation regions 64′ may also overlap gate isolation regions 64′ to provide some process margin in accordance with alternative embodiments.

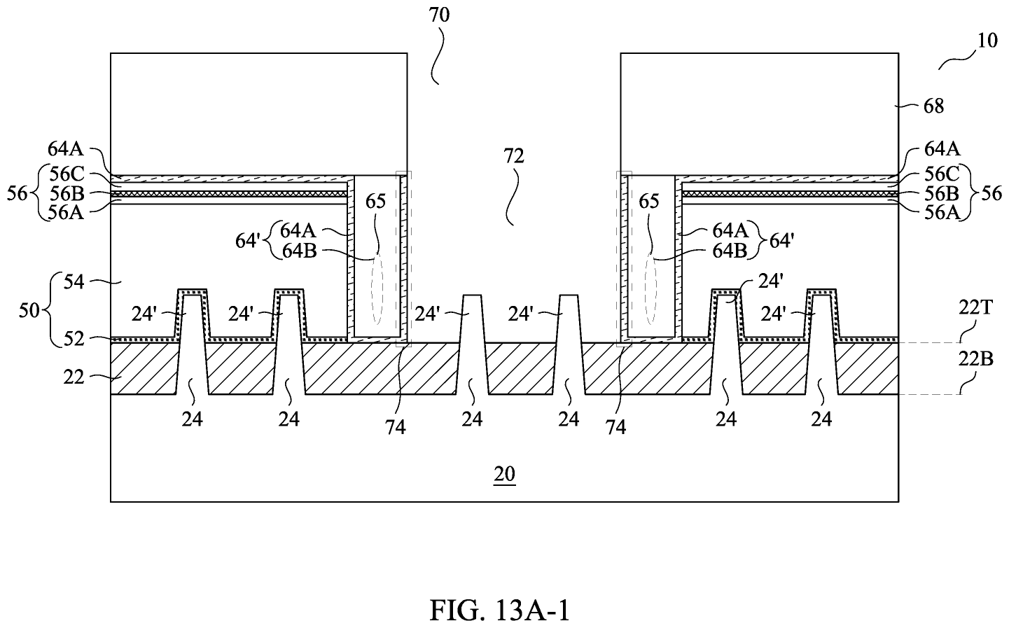

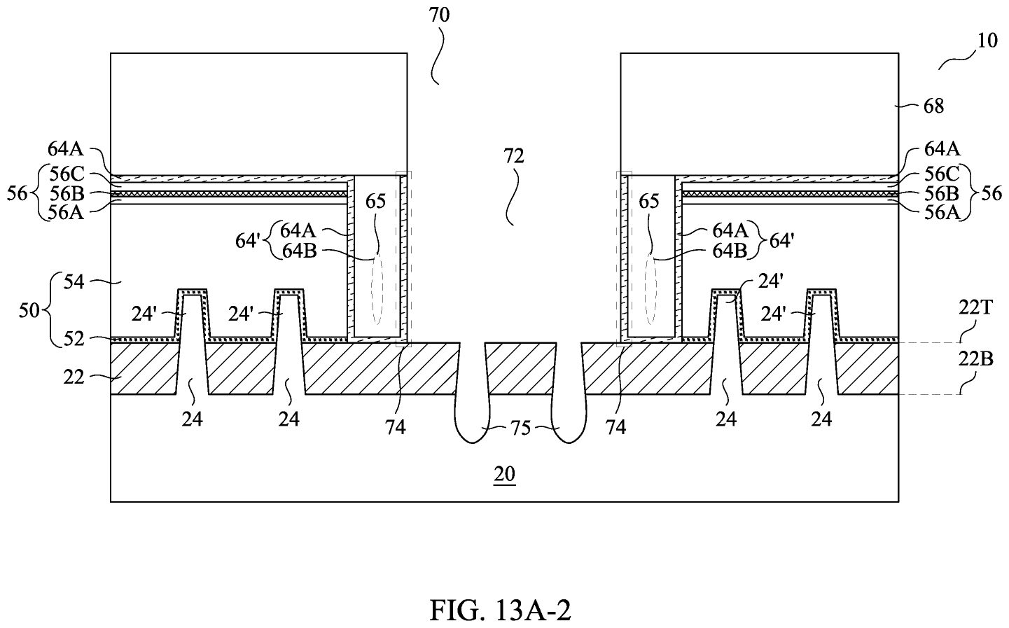

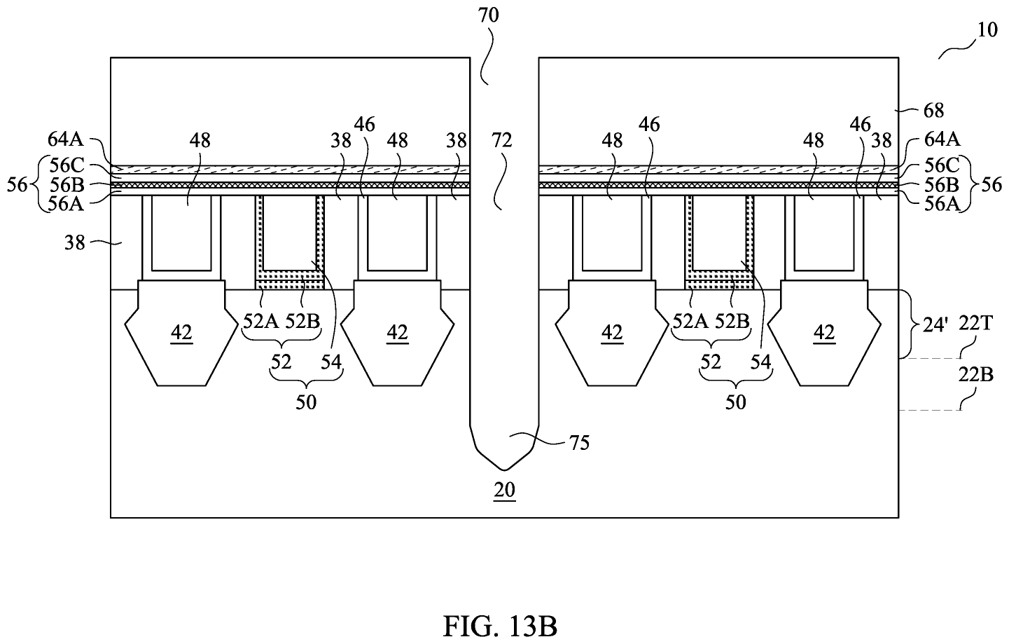

The etching mask 68 as shown in FIGS. 11, 12A, and 12B is then used to etch the underlying dielectric liner 64A, hard mask layers 56, and replacement gate stack 50, so that trenches 72 are formed extends into replacement gate stacks 50. The respective process is illustrated as process 224 in the process flow 200 as shown in FIG. 17. The resulting structure is shown in FIG. 13A-1. Protruding semiconductor fins 24′ are thus exposed. In accordance with some embodiments, the etching of dielectric liner 64A and hard mask layers 56 may include a main etching process followed by an over-etching process. The main etching process may be performed using process gases selected from CH₂F₂, CF₄, O₂, Ar, and combinations thereof. The over-etching process may be performed using process gases selected from CH₃F, O₂, Ar, and combinations thereof. The etching is anisotropic.

The etching of replacement gate stacks 50 is based on the material of replacement gate stacks 50, and may include a first etching process and a second etching process following the first etching process. The first etching process may be performed using HCl, H₂O₂, and H₂O as the etching chemical (through dry etching to remove gate electrode). The first etching process may be performed at an elevated temperature, for example, between about 50° C. and about 80° C. The etching duration may be in the range between about 150 seconds and about 200 seconds. The second etching process may be performed using H₂SO₄ as the etching chemical (through wet etching to remove the gate dielectrics). The second etching process may be performed at an elevated temperature, for example, between about 150° C. and about 200° C., for a duration in the range between about 20 seconds and about 100 seconds.

In accordance with some embodiments, the dielectric liner portions 64A in regions 74 remain after the etching process. In accordance with alternative embodiments, the dielectric liner portions 64A in regions 74 may be removed. The removal or the remaining of the dielectric liner portions 64A in regions 74 is affected by several factors such as the positions of the edges of etching mask 68, process variations, and the like, materials, and etching chemicals. Also, it is possible that some of the dielectric liner portions 64A in some regions 74 are removed, while some other dielectric liner portions 64A in some other regions 74 are not removed. For example, the dielectric liner portions 64A in the region 74 shown in FIG. 13A-1 may remain in an example, while the dielectric liner portions 64A in the right region 74 shown in FIG. 13A-1 may be removed, exposing the sidewall of the corresponding dielectric filling-region 64B.

Next, protruding fins 24′ are etched. The respective process is illustrated as process 226 in the process flow 200 as shown in FIG. 17. After the protruding fins 24′ are removed, the underlying semiconductor strips 24, which are between STI regions 22, are also etched, resulting in trenches 75. The resulting structure is shown in FIG. 13A-2. The etching may be performed until the resulting trenches 75 have bottoms lower than the bottom surfaces 22B of STI regions 22. Accordingly, trenches 75 extend into the bulk portion of substrate 20 underlying STI regions 22.

FIG. 13B illustrates a cross-sectional view of the structure shown in FIG. 13A-2, and the cross-sectional view is obtained from the same vertical plane adopted by FIG. 12B.

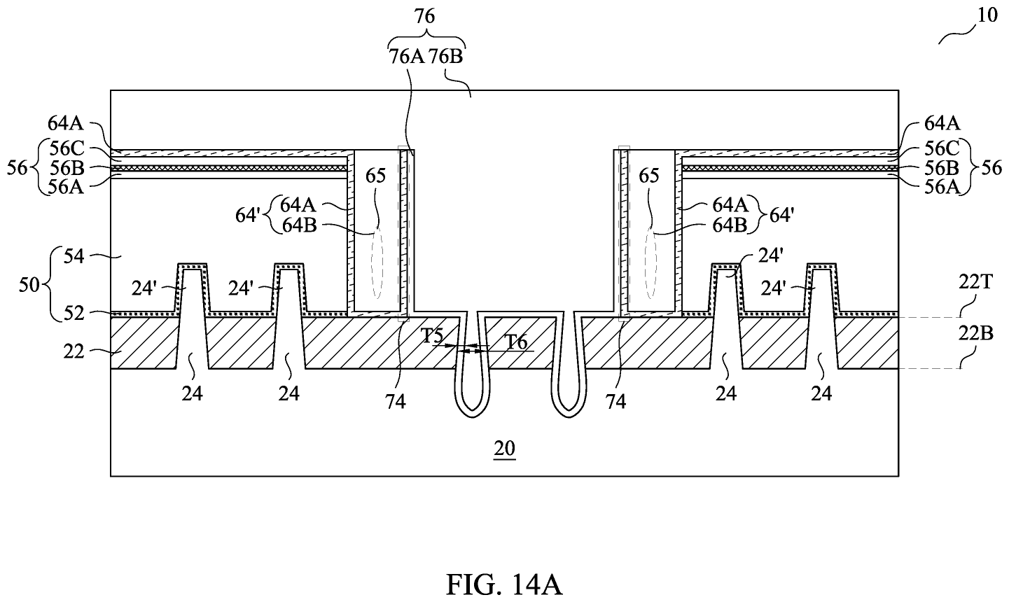

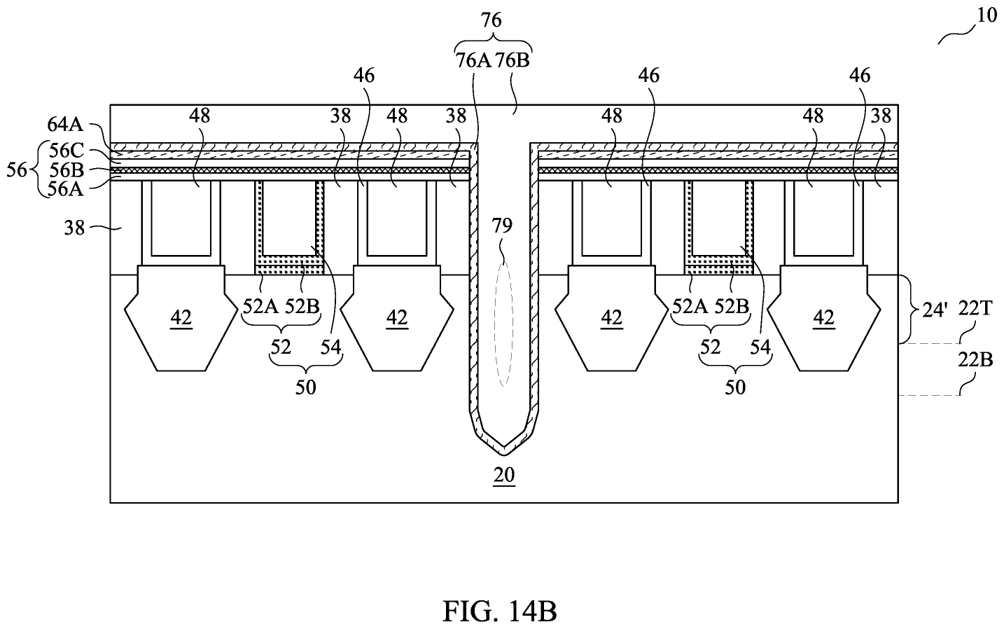

The remaining portions of trenches 72 and 75 as shown in FIGS. 13A-2 and 13B are then filled with dielectric layers 76, as shown in FIGS. 14A and 14B. The respective process is illustrated as process 228 in the process flow 200 as shown in FIG. 17. In accordance with some embodiments, dielectric layers 76 include dielectric liner 76A, and dielectric filling-region 76B over dielectric liner 76A. There may be, or may not be, seam 79 formed in dielectric filling-region 76B. The materials of dielectric liner 76A and dielectric filling-region 76B are different from each other. In accordance with some embodiments, the compositions of dielectric liner 76A and dielectric filling-region 76B are inversed than the compositions of dielectric liner 64A and dielectric filling-region 64B, respectively, as will be discussed in detail in subsequent paragraphs.

In accordance with some embodiments the portions of dielectric liner 64A in regions 74 are removed, dielectric liner 76A may be in physical contact with the dielectric filling-region 76B to form vertical interfaces. Otherwise, when the portions of dielectric liner 64A in regions 74 are not removed, dielectric liners 64A and 76 are in contact with each other to form vertical interfaces.

Dielectric liner 76A may have a higher oxygen atomic percentage than dielectric filling-region 76B, and dielectric filling-region 76B may have a higher nitrogen atomic percentage than dielectric liner 76A. This is inversed than dielectric layers 64. In accordance with some embodiments, dielectric liner 76A is formed of silicon oxide, and is free from nitrogen therein, and dielectric filling-region 76B is formed of silicon nitride, and is free from oxygen therein. In accordance with alternative embodiments, both of dielectric liner 76A and dielectric filling-region 76B comprise silicon oxynitride, and the nitrogen atomic percentage in dielectric liner 76A is lower than the nitrogen atomic percentage in dielectric filling-region 76B, while the oxygen atomic percentage in dielectric liner 76A is higher than the oxygen atomic percentage in dielectric filling-region 76B. For example, the nitrogen atomic percentage in dielectric liner 76A may be in the range between about 5 percent and about 40 percent, and the nitrogen atomic percentage in dielectric filling-region 76B may be in the range 40 percent and about 70 percent. On the other hand, the oxygen atomic percentage in dielectric liner 76A may be in the range between about 40 percent and about 70 percent, and the oxygen atomic percentage in dielectric filling-region 76B may be in the range 5 percent and about 40 percent.

In accordance with some embodiment, either one or both of dielectric liner 76A and dielectric filling-region 76B are deposited as having a uniform composition with a uniform silicon atomic percent, a uniform oxygen atomic percentage, and a uniform nitrogen atomic percentage. In accordance with alternative embodiments, either one or both of dielectric liner 76A and dielectric filling-region 76B includes a portion that has gradually changed atomic percentages of nitrogen and oxygen. For example, dielectric liner 76A may be formed of silicon oxide (or SiON), and the process gases are gradually changed to increase the flow of the precursor for adding nitrogen, so that more nitrogen may be added to upper layers, and to reduce the flow of the precursor for adding oxygen. There may be (or may not be) a bottom layer that has a uniform composition, with the bottom layer being a silicon oxide layer or an SiON layer. The process condition may be changed until a top most layer is a silicon nitride layer or a silicon oxynitride layer. In accordance with these embodiments, the gradually changed layer and the top silicon nitride layer (or SiON layer) may be collectively considered as parts of dielectric filling-region 76B, while the bottom silicon oxide layer (or SiON layer) may be considered as the dielectric liner.

In accordance with some embodiments, each of dielectric liner 76A and dielectric filling-region 76B may be formed using ALD, CVD, or the like. The precursors and the formation process conditions of dielectric liner 76A and dielectric filling-region 76B may be found referring to the formation of dielectric filling-region 64B and dielectric liner 64A, respectively, and hence are not repeated herein.

In accordance with some embodiment, the thickness of dielectric liner 76A is controlled to be not too thick and not too thin. If dielectric liner 76A (which may comprise silicon oxide) is too thick (or the entire trenches 72 and 75 are filled with silicon oxide), the threshold voltage of the neighboring FinFET will be undesirably shifted. If dielectric liner 76A is too thin (or is not formed), since silicon nitride has high leakage, without the leakage-isolation ability provided by the silicon oxide dielectric liner, the leakage current may undesirably increase.

In accordance with some embodiment, the thickness ratio T5/T6 (FIG. 14A) may be smaller than about 0.1, or may be smaller than about 0.05, wherein thickness T5 is the thickness of dielectric liner 76A, and thickness T6 is the total thickness of dielectric liner 76A and dielectric filling-region 76B. Thicknesses T5 and T6 may be measured at the middle height of STI regions 22.

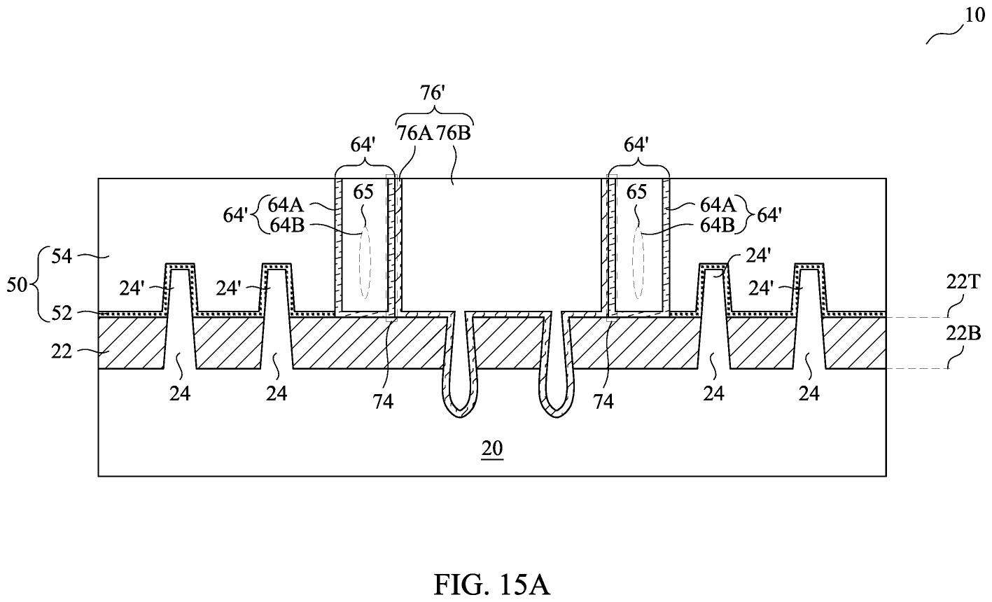

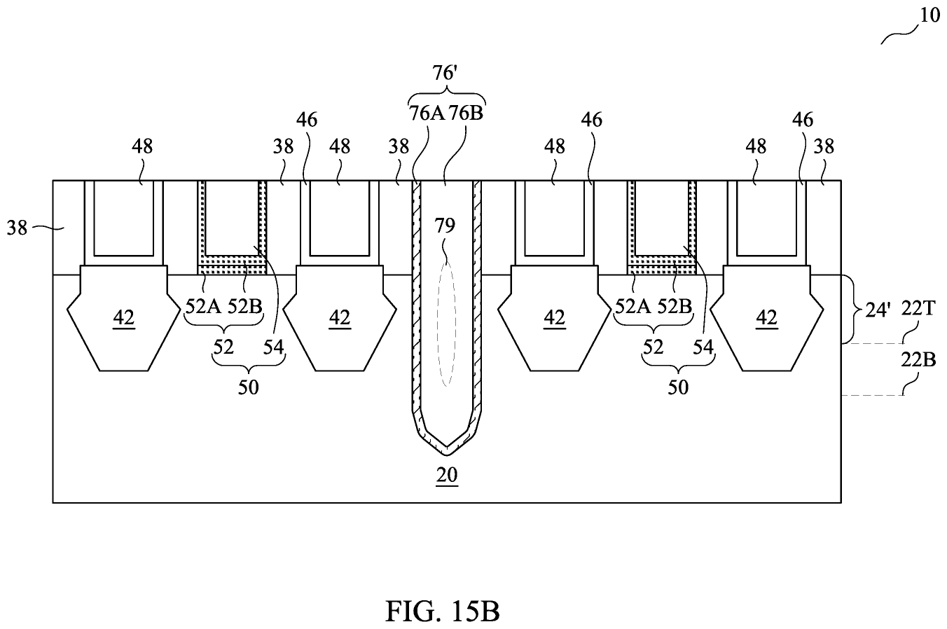

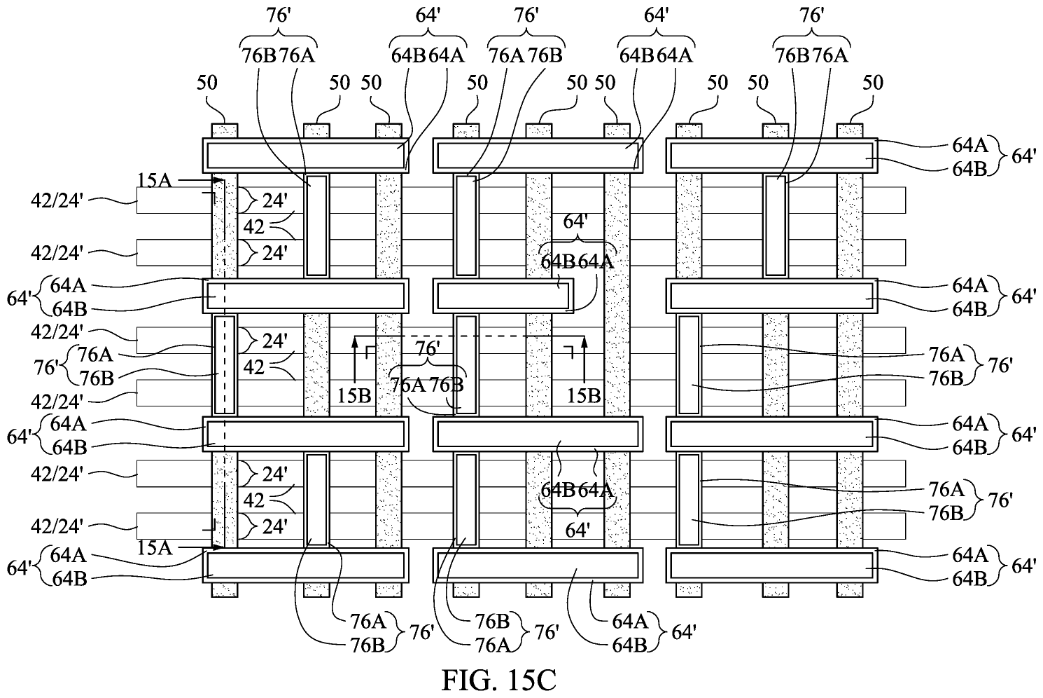

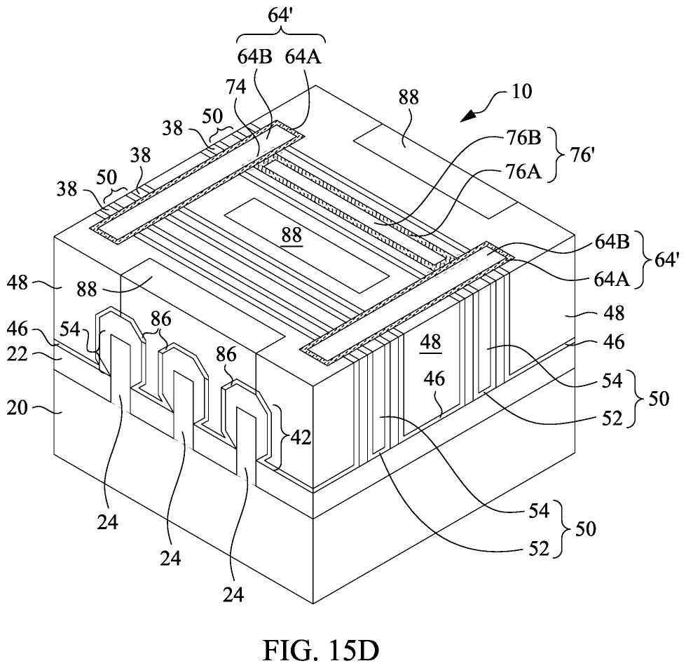

After the deposition of dielectric liner 76A and dielectric filling-region 76B, a planarization process such as a CMP process or a mechanical grinding process is performed. The respective process is illustrated as process 230 in the process flow 200 as shown in FIG. 17. The planarization process may be stopped when ILD 48, CESL 46, and replacement gate stacks 50 are exposed. The resulting structure is shown in FIGS. 15A and 15B. The remaining portions of dielectric liner 76A and dielectric filling-region 76B are collectively referred to as fin isolation regions 76′ hereinafter, and may alternatively be referred to as dielectric plugs 76′. FIG. 15C illustrates a top view of the structure shown in FIGS. 15A and 15B.

FIG. 15A illustrates the cross-section 15A-15A in FIG. 15C. FIG. 15B illustrates the cross-section 15B-15B in FIG. 15C. FIG. 15D illustrates a perspective view of a portion of the structure shown in FIGS. 15A, 15B, and 15C. In FIG. 15D, gate isolation regions 64′ are next to and joined to fin isolation regions 76′. Also, the regions 74, from which some portions of dielectric liner 64A may be removed, are also marked.

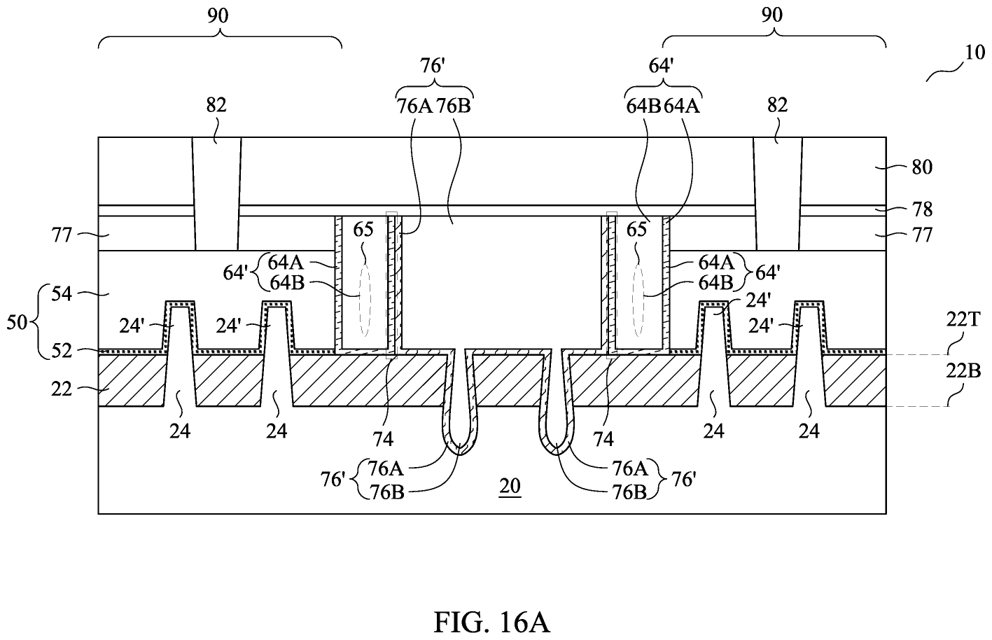

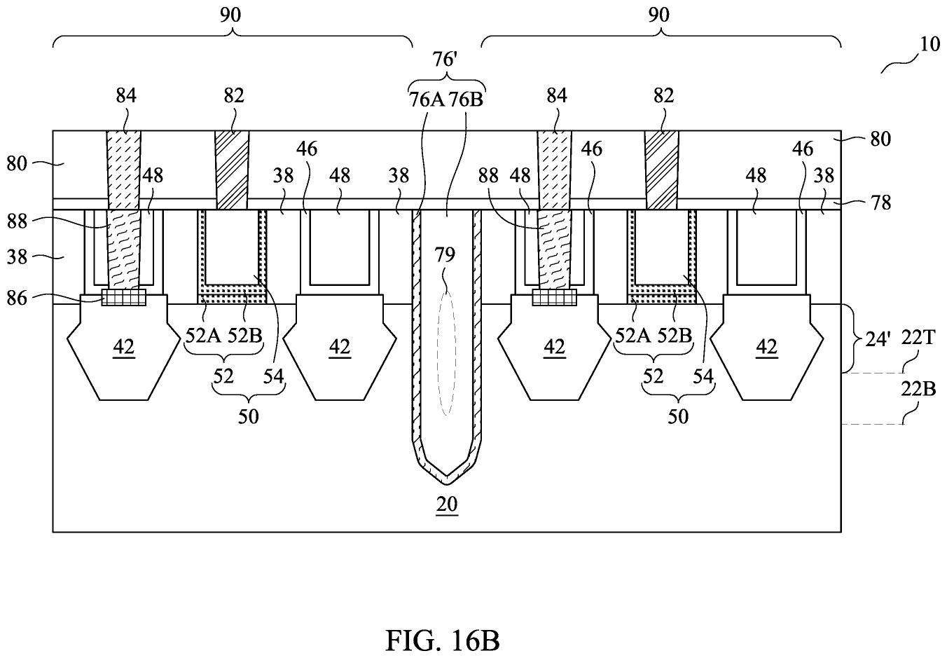

FIGS. 16A and 16B illustrate the formation of some upper features, which include dielectric hard masks 77, etch stop layer 78, ILD 80, gate contact plug 82 (FIG. 16A), source/drain contact plugs 84 and 88 (FIG. 16B), and source/drain silicide regions 86. FinFETs 90 are thus formed. The respective process is illustrated as process 232 in the process flow 200 as shown in FIG. 17.

As shown in FIG. 16A, FinFETs 90 are isolated from each other by gate isolation regions 64′ (also referred to as CMG regions 64′) and fin isolation regions 76′ (also referred to as CMODE regions 74′), both may be dual-layer regions. Gate isolation regions 64′ may have inversed compositions of oxygen and nitrogen compared to fin isolation regions 76′. Furthermore, as shown in FIG. 16A, the portions of dielectric liner 64 in regions 74 may exist, or may be removed. When removed, dielectric filling-regions 64B and dielectric liner 76A will be in physical contact with each other to form vertical interfaces.

The embodiments of the present disclosure have some advantageous features. The using of silicon-oxide-based dielectric liners in the fin isolation regions (CMODE) may help to reduce leakage current and increase breakdown voltage, while the using of SiN-based material for the corresponding dielectric filling-regions in the CMODE regions may prevent the threshold voltage of the nearby transistors to be undesirably shifted. The using of silicon-oxide-based material for the corresponding dielectric filling-regions in the CMG regions may reduce the k value of the CMG regions, and help to prevent the threshold voltage of the nearby transistors to be undesirably shifted. The use of SiN-based dielectric liner for the gate isolation regions may improve the adhesion to replacement gate stacks.

In accordance with some embodiments of the present disclosure, a method comprises forming a gate stack on a semiconductor region, wherein the semiconductor region is over a bulk semiconductor substrate; etching the gate stack to form a first trench, wherein the first trench separates the gate stack into a first gate stack portion and a second gate stack portion; forming a gate isolation region filling the first trench, wherein the gate isolation region comprises a silicon nitride liner; and a silicon oxide filling-region overlapping a first bottom portion of the silicon nitride liner; etching the gate stack to form a second trench, wherein a protruding semiconductor fin is revealed to the second trench; etching the protruding semiconductor fin to extend the second trench into the bulk semiconductor substrate; and forming a fin isolation region filling the second trench, wherein the fin isolation region comprises a silicon oxide liner; and a silicon nitride filling-region overlapping a second bottom portion of the silicon oxide liner.

In an embodiment, the silicon nitride liner in the gate isolation region comprises a first sidewall contacting a second sidewall of the silicon oxide liner in the fin isolation region. In an embodiment, when the second trench is formed, a vertical portion of the silicon nitride liner in the gate isolation region is removed, and wherein the silicon oxide filling-region in the gate isolation region contacts the silicon oxide liner in the fin isolation region to form a vertical interface. In an embodiment, when the first trench is formed, a plurality of gate stacks are etched simultaneously, with the plurality of gate stacks comprising the gate stack. In an embodiment, the etching the gate stack to form the first trench comprises forming a plurality of hard mask layers; and patterning the plurality of hard mask layers, wherein the first trench is formed using the plurality of hard mask layers as an etching mask. In an embodiment, the method further comprises, before the etching the gate stack to form the second trench, etching-through the plurality of hard mask layers.

In an embodiment, the plurality of hard mask layers comprise a first silicon nitride layer; a silicon layer over the first silicon nitride layer; and a second silicon nitride layer over the silicon layer. In an embodiment, the first trench penetrates through a shallow trench isolation region, and the first trench stops on the bulk semiconductor substrate. In an embodiment, when the first trench is formed, an additional gate stack neighboring the gate stack is etched, and the first trench continuously extends into spaces left by removed portions of the gate stack and the additional gate stack; and a space left by a top portion of a shallow trench isolation region. In an embodiment, after the first trench is formed, a bottom portion of the shallow trench isolation region remains.

In accordance with some embodiments of the present disclosure, a structure comprises a first gate stack on a semiconductor region, wherein the first gate stack comprises a first gate stack portion and a second gate stack portion; a gate isolation region between the first gate stack portion and the second gate stack portion, wherein the gate isolation region comprises a first dielectric liner; and a first filling-region overlapping a first bottom portion of the first dielectric liner; and a fin isolation region penetrating through a second gate stack, and penetrating through a shallow trench isolation region underlying the second gate stack, wherein the fin isolation region comprises a second dielectric liner, wherein the first dielectric liner has a different nitrogen atomic percentage than the second dielectric liner; and a second filling-region overlapping a second bottom portion of the second dielectric liner, wherein the first filling-region has a different oxygen atomic percentage than the second filling-region.

In an embodiment, the first dielectric liner comprises a first sidewall contacting a second sidewall of the second dielectric liner to form a vertical interface. In an embodiment, the first filling-region contacts the second dielectric liner to form a vertical interface. In an embodiment, the first dielectric liner comprises silicon nitride, and the second dielectric liner comprises silicon oxide, the first filling-region comprises silicon oxide, and the second filling-region comprises silicon nitride. In an embodiment, the first dielectric liner and the second filling-region are substantially free from oxygen therein, and the first filling-region and the second dielectric liner are substantially free from nitrogen therein. In an embodiment, each of the first dielectric liner, the second dielectric liner, the first filling-region, and the second filling-region comprises silicon oxynitride. In an embodiment, the first gate stack and the second gate stack are portions of a same elongated gate stack.

In accordance with some embodiments of the present disclosure, a structure comprises a gate stack on a semiconductor region, wherein the gate stack has a first lengthwise direction; a source region and a drain region on opposing sides of the gate stack; a gate isolation region contacting an end of the gate stack, wherein the gate isolation region has a second lengthwise direction perpendicular to the first lengthwise direction, and wherein the gate isolation region comprises a silicon nitride liner; and a silicon oxide filling-region overlapping a first bottom portion of the silicon nitride liner; and a fin isolation region having a third lengthwise direction parallel to the first lengthwise direction, wherein the gate stack and the fin isolation region contact opposite sidewalls of the gate isolation region, and wherein the fin isolation region comprises a silicon oxide liner; and a silicon nitride filling-region overlapping a second bottom portion of the silicon oxide liner. In an embodiment, the gate stack and the fin isolation region are aligned in a straight line. In an embodiment, both of the silicon nitride liner and the silicon oxide liner are conformal layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a gate stack on a semiconductor region, wherein the semiconductor region is over a bulk semiconductor substrate;
etching the gate stack to form a first trench, wherein the first trench separates the gate stack into a first gate stack portion and a second gate stack portion;
forming a gate isolation region filling the first trench, wherein the gate isolation region comprises:
a silicon nitride liner; and
a silicon oxide filling-region overlapping a first bottom portion of the silicon nitride liner;
etching the gate stack to form a second trench, wherein a protruding semiconductor fin is revealed to the second trench;
etching the protruding semiconductor fin to extend the second trench into the bulk semiconductor substrate; and
forming a fin isolation region filling the second trench, wherein the fin isolation region comprises:
a silicon oxide liner; and
a silicon nitride filling-region overlapping a second bottom portion of the silicon oxide liner.

2. The method of claim 1, wherein the silicon nitride liner in the gate isolation region comprises a first sidewall contacting a second sidewall of the silicon oxide liner in the fin isolation region.

3. The method of claim 1, wherein when the second trench is formed, a vertical portion of the silicon nitride liner in the gate isolation region is removed, and wherein the silicon oxide filling-region in the gate isolation region contacts the silicon oxide liner in the fin isolation region to form a vertical interface.

4. The method of claim 1, wherein when the first trench is formed, a plurality of gate stacks are etched simultaneously, with the plurality of gate stacks comprising the gate stack.

5. The method of claim 1, wherein the etching the gate stack to form the first trench comprises:
forming a plurality of hard mask layers; and
patterning the plurality of hard mask layers, wherein the first trench is formed using the plurality of hard mask layers as an etching mask.

6. The method of claim 5 further comprising, before the etching the gate stack to form the second trench, etching-through the plurality of hard mask layers.

7. The method of claim 5, wherein the plurality of hard mask layers comprise:
a first silicon nitride layer;
a silicon layer over the first silicon nitride layer; and
a second silicon nitride layer over the silicon layer.

8. The method of claim 1, wherein the first trench penetrates through a shallow trench isolation region, and the first trench stops on the bulk semiconductor substrate.

9. The method of claim 1, wherein when the first trench is formed, an additional gate stack neighboring the gate stack is etched, and the first trench continuously extends into:
spaces left by removed portions of the gate stack and the additional gate stack; and
a space left by a top portion of a shallow trench isolation region.

10. The method of claim 9, wherein after the first trench is formed, a bottom portion of the shallow trench isolation region remains.

11. A structure comprising:
a first gate stack on a semiconductor region, wherein the first gate stack comprises a first gate stack portion and a second gate stack portion;
a gate isolation region between the first gate stack portion and the second gate stack portion, wherein the gate isolation region comprises:
a first dielectric liner; and
a first filling-region overlapping a first bottom portion of the first dielectric liner; and
a fin isolation region penetrating through a second gate stack, and penetrating through a shallow trench isolation region underlying the second gate stack, wherein the fin isolation region comprises:
a second dielectric liner, wherein the first dielectric liner has a different nitrogen atomic percentage than the second dielectric liner; and
a second filling-region overlapping a second bottom portion of the second dielectric liner, wherein the first filling-region has a different oxygen atomic percentage than the second filling-region.

12. The structure of claim 11, wherein the first dielectric liner comprises a first sidewall contacting a second sidewall of the second dielectric liner to form a vertical interface.

13. The structure of claim 11, wherein the first filling-region contacts the second dielectric liner to form a vertical interface.

14. The structure of claim 11, wherein the first dielectric liner comprises silicon nitride, and the second dielectric liner comprises silicon oxide, the first filling-region comprises silicon oxide, and the second filling-region comprises silicon nitride.

15. The structure of claim 14, wherein the first dielectric liner and the second filling-region are substantially free from oxygen therein, and the first filling-region and the second dielectric liner are substantially free from nitrogen therein.

16. The structure of claim 11, wherein each of the first dielectric liner, the second dielectric liner, the first filling-region, and the second filling-region comprises silicon oxynitride.

17. The structure of claim 11, wherein the first gate stack and the second gate stack are portions of a same elongated gate stack.

18. A structure comprising:
a gate stack on a semiconductor region, wherein the gate stack has a first lengthwise direction;
a source region and a drain region on opposing sides of the gate stack;
a gate isolation region contacting an end of the gate stack, wherein the gate isolation region has a second lengthwise direction perpendicular to the first lengthwise direction, and wherein the gate isolation region comprises:
a silicon nitride liner; and
a silicon oxide filling-region overlapping a first bottom portion of the silicon nitride liner; and
a fin isolation region having a third lengthwise direction parallel to the first lengthwise direction, wherein the gate stack and the fin isolation region contact opposite sidewalls of the gate isolation region, and wherein the fin isolation region comprises:
a silicon oxide liner; and
a silicon nitride filling-region overlapping a second bottom portion of the silicon oxide liner.

19. The structure of claim 18, wherein the gate stack and the fin isolation region are aligned in a straight line.

20. The structure of claim 18, wherein both of the silicon nitride liner and the silicon oxide liner are conformal layers.
